(19) United States
(12) Patent Application Publication
(10) Pub. No.: US 2014/0266813 A1
(43) Pub. Date: Sep. 18, 2014

(54) ELECTRONIC DEVICE WITH BOUNCE PROTECTION CIRCUIT

(71) Applicants: HON HAI PRECISION INDUSTRY CO., LTD., New Taipei (TW); HONG FU JIN PRECISION INDUSTRY (ShenZhen) Co., LTD, Shenzhen (CN)

(72) Inventors: YA-GUO WANG, Shenzhen (CN); CHUN-CHING CHEN, New Taipei (TW)

(73) Assignees: HON HAI PRECISION INDUSTRY CO., LTD, New Taipei (TW); HONG FU JIN PRECISION INDUSTRY (ShenZhen) Co., LTD, Shenzhen (CN)

(21) Appl. No.: 14/016,397

(22) Filed: Sep. 3, 2013

(30) Foreign Application Priority Data
Mar. 12, 2013 (CN) 2013100778390

(51) Int. Cl. H03M 11/00

(52) U.S. Cl. CPC H03M 11/003
USPC 341/24

(57) ABSTRACT

An electronic device with an anti-bounce key function includes a first voltage module, a second voltage module, a key module, a processor, and a bounce protection circuit. The first voltage module provides a first voltage, and the second voltage module provides a second voltage. The key module with a number of keys generates a pressing signal when a key is pressed. The bounce protection circuit connected between the key module and the processor is powered by the first voltage module. Each of the keys, when pressed, corresponds to a predetermined period of time. The bounce protection circuit counts time when the key module generates a pressed signal, and transmits the pressed signal to the processor when the elapsed time is more than the predetermined period of time corresponding to the pressed key.

### BACKGROUND

1. Technical Field

The present disclosure relates to an electronic device with a bounce protection circuit.

2. Description of Related Art

Keys which must be physically operated generate a pressing signal for executing a corresponding function when pressed. However, the pressed mechanical key may rebound several times, thus the same corresponding pressing signal is generated repeatedly.

Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout two views.

FIG. 1 is a block diagram of an electronic device in accordance with one embodiment.

FIG. 2 is a circuit diagram of the electronic device of FIG. 1 in accordance with one embodiment.

FIG. 3 is a circuit diagram of the electronic device of FIG. 1 in accordance with another embodiment.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at “least one.”

FIG. 1 shows an electronic device 100 of one embodiment of the present disclosure. The electronic device 100 includes a number of keys 32, 34, and 36 for generating a pressing signal when pressed. The electronic device 100 is prevented from repeatedly executing a function due to a bounced key. In the embodiment, the keys are mechanical keys.

The electronic device 100 includes a first voltage module 10, a second voltage module 20, a key module 30, a processor 40, and a bounce protection circuit 50.

The first voltage module 10 provides a first voltage. In the embodiment, the first voltage is a high level voltage signal.

The second voltage module 20 connects to the first voltage module 10 through the key module 30, and provides a second voltage. In the embodiment, the second voltage is a low level voltage signal.

The key module 30 connects to the second voltage module 20 and the bounce protection module 50. The key module 30 includes a number of keys 32, 34, and 36, and generates a signal when any of the keys 32, 34, and 36 is pressed. In the embodiment, the signal is a logic low level voltage signal.

The processor 40 includes a first port P1 and a second port P2. The processor 40 sets the voltage of the first port P1 and a second port P2 according to a predetermined rule, and then detects whether the voltages of the first port P1 and the second port P2 are changed by a signal from a pressed key. When either one of the voltages of the first port P1 and the second port P2 is changed, the processor 40 recognizes the key which has been pressed and executes a corresponding function. In the embodiment, in the predetermined rule, the processor 40 firstly sets the first port P1 and the second port P2 in a logic high voltage level, and then sets the second port P2 into a logic low voltage level when neither of the voltages of the first port P1 and the second port P2 are changed. In other embodiments, the processor 40 can include more than two ports.

The bounce protection circuit 50 connects to the first voltage 10, the key module 30, and the processor 40. The bounce protection circuit 50 counts a time when any of the keys 32, 34, and 36 is pressed, and transmits the signal from the pressed key to the processor 40 when the period of accumulated time is more than a predetermined period. The bounce protection circuit 50 includes a first protection module 51 and a second protection module 52. The first protection module 51 is connected to the first port P1, and the second protection module 52 is connected to the second port P2. The keys 32, 34, and 36 correspond to different predetermined periods of time in a one-to-one relationship, and the predetermined periods of time can be set by operations of users. In other embodiments, the bounce protection circuit 50 can include more than two protection modules corresponding to the ports of the processor 40 in a one-to-one relationship.

FIG. 2 shows a circuit diagram of the electronic device 100 in accordance with one embodiment. The first voltage module 10 includes a power source Vcc, a first resistor R1, and a second resistor R2. The first resistor R1 and the second resistor R2 are connected between the power source Vcc and the bounce protection module 50.

The second voltage module 20 includes a ground port 21. In another embodiment, the second voltage module 20 further includes a pull-up resistor R5 (see FIG. 3).

The key 32 and the key 34 are connected between the first voltage module 10 and the second voltage module 20 in parallel, opposite terminals of the key 36 are respectively connected to the bounce protection circuit 50.

The processor 40 includes a first port P1 and a second port P2. The first port P1 and the second port P2 are connected to the bounce protection circuit 50 in parallel, and are respectively connected to the first resistor R1 and the second resistor R2.

The bounce protection module 50 includes a first protection module 51 and a second protection module 52. The first protection module 51 includes a first protecting resistor R3 and a first capacitor C1. A terminal of the first protecting resistor R3 is connected to the first port P1, and the opposite terminal of the first protecting resistor R3 is connected to the key 32. A terminal of the first capacitor C1 is connected to the first port P1, and the opposite terminal of the first capacitor C1 is grounded. The second protection module 52 includes a second protecting resistor R4 and a second capacitor C2. A terminal of the second protecting resistor R4 is connected to the second port P2, and the opposite terminal of the second protecting resistor R4 is connected to the key 32. A terminal of the second capacitor C1 is connected to the second port P2, and the opposite terminal of the second capacitor C1 is grounded. In the embodiment, the resistances of the first protecting resistor R3 and the second protecting resistor R4 are adjustable, and the capacitances of the first capacitor C1 and the second capacitor C2 are adjustable.

The principle of the electronic device 100 is described as follows, the first capacitor C1 and the second capacitor C2 are charged by the voltage of the power source Vcc. When the key 32 is pressed, the processor 40 sets the first port P1 and the second port P2 at the logic high level. The first capacitor C1 is discharged for a first predetermined time through the first protecting resistor R3. After the first predetermined time, the voltage of the first port P1 changes to 0V. Thus, the processor 40 recognizes the key 32 is pressed. The first predetermined time T1 is calculated according to the formula T1=C1*R3.

When the key 34 is pressed, the processor 40 sets the first port P1 and the second port P2 at the logic high level. The second capacitor C2 is discharged for a second predetermined time through the second protecting resistor R4. After the second predetermined time, the voltage of the second port P2 changes to 0V. Thus, the processor 40 recognizes the key 34 is pressed. The second predetermined time T2 is calculated according to the formula T2=C2*R4.

When the key 36 is pressed, the processor 40 sets the first port P1 and the second port P2 at the logic high level. The voltages of the first port P1 and the second port P2 are not changed, the processor 40 further sets the second port P2 in a logic low voltage level. The first capacitor C1 and the second capacitor C2 are discharged together for a third predetermined time through the first protecting resistor R3 and the second protecting resistor R4. After the third predetermined time, the voltage of the first port P1 changes to 0V. Thus, the processor 40 recognizes the key 36 is pressed. The third predetermined time T3 is calculated according to the formula T3=(C1+C2)*(R3+R4).

FIG. 3 shows a circuit diagram of the electronic device 100 in accordance with another embodiment. The second voltage module 20 further includes a pull-up resistor R5. A terminal of the pull-up resistor R5 is connected to the key 32 and the key 34, the opposite terminal of the pull-up resistor R5 is connected to the ground port 21. The second protection module 52 omits the second protecting resistor R4.

In use, when the keys are bouncing, the signal from a pressed key cannot be transmitted by the processor. Therefore, misoperation of keys of the electronic device 100 when the keys are bouncing is reduced.

It is to be understood, however, that even though information and advantages of the present embodiments have been set forth in the foregoing description, together with details of the structures and functions of the present embodiments, the disclosure is illustrative only; and changes may be made in detail, especially in the matters of shape, size, and arrangement of parts within the principles of the present embodiments to the full extent indicated by the broad general meaning of the terms in which the appended claims are expressed.

What is claimed is:

1. An electronic device comprising:
a first voltage module providing a first voltage;
a second voltage module providing a second voltage;
a key module with a plurality of keys each generating a corresponding pressing signal when pressed;
a processor executing a corresponding function in response to the pressing signal; and
a bounce protection circuit connected between the key module and the processor and powered by the first voltage module;
wherein each of the keys in the key module corresponds to a predetermined period of time; the bounce protection circuit accumulates time when the key module generates a pressing signal, and transmits the pressing signal to the processor when the accumulated time is more than the corresponding predetermined period of time corresponding to the pressed key.

2. The electronic device of claim 1, wherein the processor comprises at least two ports; the bounce protection circuit comprises at least two protection modules corresponding to the at least ports in one-to-one relationship; the processor sets the voltage of the at least two ports in a predetermined rule and detects whether the voltages of the at least two ports are changed by the transmitted pressing signal; when one of the voltages of the at least ports is changed, the processor recognizes the pressed key and executes a corresponding function.

3. The electronic device of claim 2, wherein the processor firstly sets the at least two ports in a logic high voltage level, and then sets one of the at least two ports into a logic low voltage level when neither the voltages of the at least two ports are not changed.

4. The electronic device of claim 2, wherein each of the at least two protection module comprises a protecting resistor and a capacitor; opposites terminals of the protecting resistor are respectively connected to the corresponding port and the key module; one terminal of the capacitor is connected to the corresponding port and the opposite terminal of the capacitor is grounded.

5. The electronic device of claim 4, wherein the resistance of the protecting resistor is adjustable to adjust the predetermined period of time.

6. The electronic device of claim 1, wherein one of the at least two protection modules comprises a capacitor; one terminal of the capacitor is connected to the corresponding port and the opposite terminal of the capacitor is grounded.

7. The electronic device of claim 1, wherein the second voltage module includes a pull-up resistor and a ground port; one terminal of the pull-up resistor is connected to the key module, the opposite terminal of the pull-up resistor is connected to the ground port.

8. The electronic device of claim 1, wherein the key module comprises at least three keys; two of the keys are connected between the second voltage module and the bounce protection circuit in parallel; opposite terminals of the rest of the at least three keys are connected to the bounce protection circuit.

9. The electronic device of claim 1, wherein the first voltage module comprises a power source and at least two resistors; the at least two resistors are connected between the power source and the processor in parallel.
